(19) United States
(12) Patent Application Publication
(10) Pub. No.: US 2026/0032968 A1
(43) Pub. Date: Jan. 29, 2026

(54) THIN FILM TRANSISTOR HAVING PROTECTION LAYER AND DISPLAY APPARATUS COMPRISING THE SAME

(71) Applicant: LG Display Co., Ltd., Seoul (KR)

(72) Inventors: Sungju CHOI, Paju-si (KR); Jaeyoon PARK, Paju-si (KR); Hyeonjoo SEUL, Paju-si (KR); Dongyeon KANG, Paju-si (KR)

(73) Assignee: LG Display Co., Ltd., Seoul (KR)

(21) Appl. No.: 19/256,104

(22) Filed: Jun. 30, 2025

(30) Foreign Application Priority Data
Jul. 24, 2024 (KR) 10-2024-0097950

(51) Int. Cl. H10D 30/67; H10K 59/121

(52) U.S. Cl. CPC H10D 30/6757; H10D 30/6755; H10K 59/1213

(57) ABSTRACT

An embodiment of the present disclosure provides a thin film transistor having a protection layer and a display apparatus including the thin film transistor. The thin film transistor includes an active layer, a first protection layer on the active layer, a gate electrode spaced apart from the active layer and the first protection layer. The active layer comprises a channel part that overlaps the gate electrode, a source connection part on one side of the channel part, and a drain connection part on the opposite side. The first protection layer contacts at least a portion of the channel part and the drain connection part, and at least a portion of the first protection layer overlaps the gate electrode. This structure improves the stability of the active layer and enhances the operational reliability of the thin film transistor, particularly in regions subjected to strong electric fields.

### CROSS-REFERENCE TO RELATED APPLICATION

This application claims the benefit of priority of the Republic of Korea Patent Application No. 10-2024-0097950 filed on Jul. 24, 2024, which is hereby incorporated by reference in its entirety.

### BACKGROUND

### Technical Field

The present disclosure relates to a thin film transistor having a protection layer and a display apparatus including the same.

### Description of the Related Art

Since thin film transistors may be manufactured on glass or plastic substrates, they are widely used as switching elements or driving elements in display apparatuses such as liquid crystal display apparatuses or organic light emitting devices.

Thin film transistors may be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, depending on the material constituting the active layer.

Among these, oxide semiconductor thin film transistor (Oxide semiconductor TFT) that have high mobility and a large resistance variation depending on the oxygen content have the advantage of being able to easily obtain desired properties. Since the oxide constituting the active layer may be formed at a relatively low temperature during the manufacturing process of oxide semiconductor thin film transistors, the manufacturing cost is low. In addition, since oxide semiconductors are transparent due to the nature of oxides, they are also advantageous in implementing transparent displays.

### BRIEF SUMMARY

When the oxide semiconductor thin film transistor is driven, a strong electric field may be applied to the drain region. During prolonged operation, this can result in localized heating at the drain region, and carriers with high kinetic energy may become trapped, leading to physical or electrical damage to the drain region.

It has been observed that in the drain region, where a strong horizontal electric field is present, carriers with high kinetic energy, sometimes referred to as hot carriers, can contribute to the deterioration of the device (e.g., damage to the drain region). Specifically, defects may form on the surface of the oxide semiconductor layer as a result of exposure to an etchant during etching process. If high-energy carriers become trapped in these defect sites, they may induce further degradation of the oxide semiconductor layer, potentially resulting in visible defects such as stains or spots in a corresponding display apparatus.

Therefore, various embodiments described herein are directed to structure that reduce or prevent damage to the oxide semiconductor layer in an oxide semiconductor thin film transistor. In particular, the structures aim to protect the drain region, which is subject to strong electric fields and is therefore especially susceptible to performance degradation.

For instance, the disclosed thin film transistor enhances electrical and structural stability by incorporating a protection layer formed from oxide semiconductor materials with high resistivity and increased concentrations of oxygen and gallium. This first protection layer is selectively positioned over the drain region and a portion of the channel to protect against damage from high-energy carriers and fabrication-related defects. Due to its thin profile and its insulating characteristics, it does not interfere with the electrical operation of the transistor. The use of shared metal elements between the active layer and the protection layer improves interface bonding and allows for effective defect passivation.

A second protection layer may be positioned beneath the active layer to further shield it from external chemical exposure such as hydrogen or oxygen diffusion from the substrate side. Together, these layers support long-term stability of the device under electrical stress, maintaining consistent threshold voltage and current flow. This structural configuration is suitable for integration into display panels, contributing to improved pixel reliability, reduced visual defects, and compatibility with low-temperature manufacturing processes.

Additional embodiments are also described. One embodiment of the present disclosure provides a method for improving a stability of an active layer and enhancing an operational stability of a thin film transistor by disposing a protection layer on an active layer.

Another embodiment of the present disclosure is to provide a thin film transistor including a protection layer disposed on an active layer, and thus having excellent stability. Another embodiment of the present disclosure is to provide a thin film transistor including a first protection layer disposed on an upper surface of an active layer and a second protection layer disposed on a lower surface of the active layer.

Another embodiment of the present disclosure is to provide a thin film transistor including a protection layer, which is made of an oxide semiconductor material and has a high oxygen concentration.

Another embodiment of the present disclosure is to provide a display apparatus including the thin film transistor.

One embodiment of the present disclosure for achieving the described technical subject provides a thin film transistor including an active layer, a first protection layer on the active layer, a gate electrode spaced apart from the active layer and the first protection layer, wherein the active layer comprises a channel part overlapping the gate electrode, a source connection part connected to one side of the channel part, and a drain connection part connected to the other side of the channel part, wherein the first protection layer contacts a portion of the channel part and the drain connection part, and a portion of the first protection layer overlaps the gate electrode.

The first protection layer may be integrally formed on upper surface of a portion of the channel part and on upper surface of at least a portion of the drain connection part.

The first protection layer contacts a side surface of a portion of the channel part and a side surface of at least a portion of the drain connection part.

The first protection layer may be disposed only at and around a borderline between the channel part and the drain connection part.

The first protection layer may include at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, a GO (GaO) based oxide semiconductor material, a TO (SnO) based oxide semiconductor material, an ITO (InSnO) based oxide semiconductor material, and an ITZO (InSnZnO) based oxide semiconductor material.

The active layer and the first protection layer may include a same metal.

The active layer and the first protection layer each may include gallium Ga, and a gallium concentration of the first protection layer is higher than a gallium concentration of the active layer, wherein the gallium concentration of the first protection layer may be calculated as a ratio of the number of gallium Ga atoms to the total number of atoms in the first protection layer, which is atomic %, i.e., at %, and the gallium concentration of the active layer may be calculated as a ratio of the number of gallium Ga atoms to the total number of atoms in the active layer, which is atomic %, i.e., at %.

The first protection layer may have a resistivity higher than a resistivity of the active layer.

The first protection layer may have a resistivity of 1.0×10⁶ Ω·cm or more.

The first protection layer may have a carrier concentration lower than a carrier concentration of the active layer.

The first protection layer may have a carrier concentration of 1.0×10¹⁶ ea/cm³ or less.

The first protection layer may have an oxygen concentration higher than an oxygen concentration of the active layer.

The first protection layer may have a thickness of 0.5 to 3 nm.

An overlap length between the first protection layer and the channel part is less than or equal to half a length of the channel part, wherein the length of the channel part is the distance between the source and drain connection parts, and the overlap length is measured in a direction parallel to a line connecting the source and drain connection parts.

The overlapping length between the first protection layer and the channel part is 0.5 μm or more.

The thin film transistor may further include a second protection layer contacting the active layer, and the active layer may be disposed on the second protection layer.

The second protection layer may contact the first protection layer.

The first protection layer may extend to a side surface of the channel part and a side surface of the drain connection part and may contact the second protection layer.

The second protection layer includes at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, a GO (GaO) based oxide semiconductor material, a TO (SnO) based oxide semiconductor material, an ITO (InSnO) based oxide semiconductor material, and an ITZO (InSnZnO) based oxide semiconductor material.

The active layer and the second protection layer each may include gallium (Ga), and the gallium (Ga) concentration of the second protection layer may be higher than that of the active layer.

The second protection layer may have a resistivity of 1.0×10⁶ Ω·cm or more.

The second protection layer may have a thickness of 0.5 to 3 nm.

The second protection layer may include a first region overlapping the active layer and a second region not overlapping the active layer, wherein the first region may have a greater thickness than the second region.

The active layer may include a first oxide semiconductor layer and a second oxide semiconductor layer on the first oxide semiconductor layer.

The first protection layer may include the same metal as the second oxide semiconductor layer.

The second protection layer may include the same metal as the first oxide semiconductor layer.

Another embodiment of the present disclosure provides a display apparatus including the thin film transistor described above.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a cross-sectional view of a thin film transistor according to another embodiment of the present disclosure.

FIG. 5 is a plan view of a thin film transistor according to another embodiment of the present disclosure.

FIG. 6 is a cross-sectional view taken along line III-III′ of FIG. 5.

FIG. 7 is a plan view of a thin film transistor according to another embodiment of the present disclosure.

FIG. 8 is a cross-sectional view taken along line IV-IV′ of FIG. 7.

FIG. 9 is a cross-sectional view taken along line V-V′ of FIG. 7.

FIG. 10 is an enlarged cross-sectional view of a portion of a thin film transistor according to another embodiment of the present disclosure.

FIG. 11 is a cross-sectional view of a thin film transistor according to another embodiment of the present disclosure.

FIG. 12 is a cross-sectional view of a thin film transistor according to another embodiment of the present disclosure.

FIG. 13A is a graph explaining the relationship between channel length L_{ch} and drain current Iₒₙ, and FIG. 13B is a graph explaining the relationship between oxygen content of a gate insulating layer and threshold voltage (Vth).

FIG. 14 is a schematic diagram of a display apparatus according to another embodiment of the present disclosure.

FIG. 15 is a circuit diagram for one pixel of FIG. 14.

FIG. 16 is a plan view of the pixel of FIG. 15.

FIG. 17 is a cross-sectional view taken along line VI-VI′ of FIG. 16.

### DETAILED DESCRIPTION

The advantages and features of the present disclosure, and the method for achieving them, will become clear with reference to the embodiments described in detail below together with the accompanying drawings. However, the present disclosure is not limited to the embodiments disclosed below, but may be implemented in various different forms. These embodiments are intended to make the disclosure of the present disclosure complete and to enable those skilled in the art to easily understand the disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same components may be referred to by the same reference numerals throughout the specification. In addition, in explaining the present disclosure, if it is determined that a detailed description of a related known technology may unnecessarily obscure the gist of the present disclosure, the detailed description is omitted.

In this specification, when the words “includes,” “has,” “consists of,” or the like, are used, other parts may be added unless the expression “only” is used. When a component is expressed in the singular, the plural is included unless otherwise explicitly stated.

When interpreting a component, it is interpreted as including the error range even if there is no separate explicit description.

For example, when the positional relationship between two parts is described as “on ˜”, “above ˜”, “below ˜”, “next to ˜”, or the like, one or more other parts may be located between the two parts, unless the expression “right” or “directly” is used.

The spatially relative terms “below,” “beneath,” “lower,” “above,” “upper,” and the like may be used to easily describe the relationship of one element or component to another element or component, as illustrated in the drawings. The spatially relative terms should be understood to include different orientations of the elements during use or operation in addition to the orientations depicted in the drawings. For example, if an element illustrated in the drawings is flipped over, an element described as “below” or “beneath” another element may end up being placed “above” the other element. Thus, the exemplary term “below” may include both the above and below directions. Likewise, the exemplary term “above” or “on” may include both the above and below directions.

As used herein, the term “connected” is intended to have the broadest possible meaning. Specifically, the phrase “A is connected to B” encompasses both a direct connection where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When describing a temporal relationship, for example, when describing a temporal relationship such as “after”, “following”, “next to”, “before”, or the like, it may also include cases where there is no continuity, as long as the expression “right away” or “directly” is not used.

Although the terms first, second, or the like. are used to describe various components, these components are not limited by these terms. These terms are only used to distinguish one component from another. Accordingly, a first component referred to below may also be a second component within the technical concept of the present disclosure.

At least one term should be understood to include all combinations that may be presented from one or more of the associated items. For example, the meaning of “at least one of the first, second, and third items” may mean not only each of the first, second, or third items, but also all combinations of items that may be presented from two or more of the first, second, and third items.

The individual features of the various embodiments of the present disclosure may be partially or wholly combined or combined with each other, and may be technically linked and driven in various ways, and each embodiment may be implemented independently of each other or may be implemented together in a related relationship.

When adding reference numerals to components of each drawing describing embodiments of the present disclosure, identical components may have the same numerals as much as possible even if they are shown in different drawings.

In the embodiments of the present disclosure, the source electrode and the drain electrode are distinguished only for convenience of explanation, and the source electrode and the drain electrode may be interchanged. In addition, the source electrode of one embodiment may become the drain electrode in another embodiment, and the drain electrode of one embodiment may become the source electrode in another embodiment.

In some embodiments of the present disclosure, for convenience of explanation, the source connection part and the source electrode are distinguished, and the drain connection part and the drain electrode are distinguished, but the embodiments of the present disclosure are not limited thereto. The source connection part may be the source electrode, and the drain connection part may be the drain electrode. In addition, the source connection part may be the drain electrode, and the drain connection part may be the source electrode.

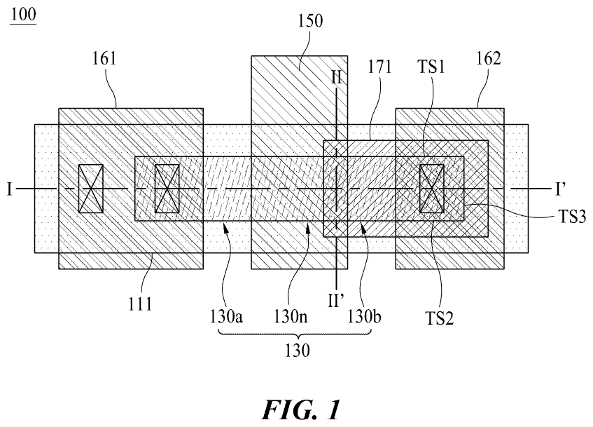

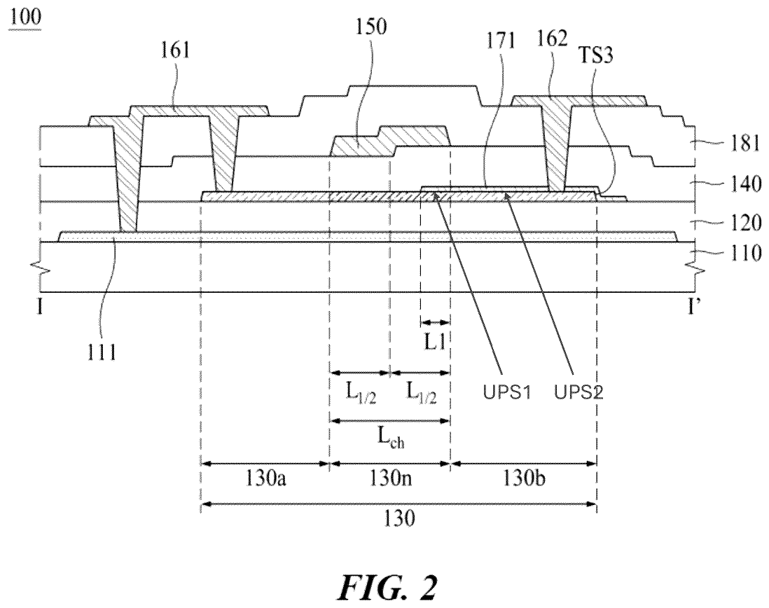

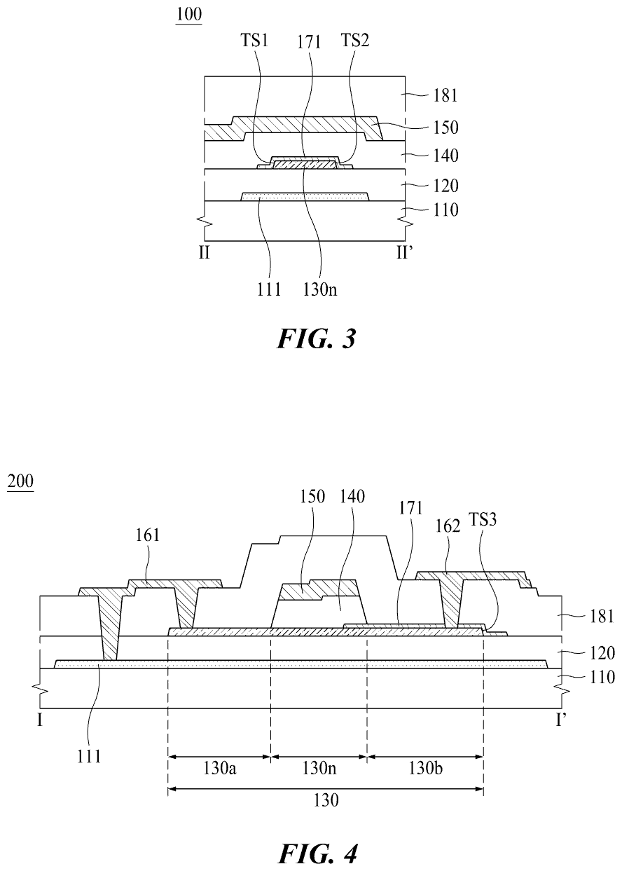

FIG. 1 is a plan view of a thin film transistor 100 according to one embodiment of the present disclosure, FIG. 2 is a cross-sectional view taken along line I-I′ of FIG. 1, and FIG. 3 is a cross-sectional view taken along line II-II′ of FIG. 1.

Referring to FIGS. 1, 2, and 3, a thin film transistor 100 according to one embodiment of the present disclosure includes an active layer 130, a first protection layer 171, and a gate electrode 150. The first protection layer 171 is disposed on the active layer 130. The gate electrode 150 is disposed on the active layer 130 and the first protection layer 171. The active layer 130 includes a channel part 130n overlapping with the gate electrode 150, a source connection part 130a connected to one side of the channel part 130n, and a drain connection part 130b connected to the other side of the channel part 130n.

According to one embodiment of the present disclosure, the first protection layer 171 contacts a portion of the channel part 130n and the drain connection part 130b. In addition, a portion of the first protection layer 171 overlaps the gate electrode 150.

Referring to FIGS. 2 and 3, a thin film transistor 100 may be disposed on a substrate 110.

The substrate 110 supports the components of the thin film transistor 100. Anything that supports the thin film transistor 100 may be the substrate 110 without limitation.

The glass substrate or a polymer resin substrate may be used as the substrate 110. As a polymer resin substrate, there is a plastic substrate. The plastic substrate may include at least one of polyimide (PI), polycarbonate (PC), polyethylene (PE), polyester, polyethylene terephthalate (PET), and polystyrene (PS) having flexible properties. When a plastic is used as the substrate 110, considering that a high temperature deposition process is performed on the substrate 110, a heat resistant plastic that may withstand high temperatures may be used.

A light blocking layer 111 may be disposed on the substrate 110. The light blocking layer 111 has light blocking property. The light blocking layer 111 may block light incident from the substrate 110 and protect the channel part 130n of the active layer 130.

The light blocking layer 111 may be made of a material having light blocking property. The light blocking layer 111 may include at least one of an aluminum based metal such as aluminum (Al) or an aluminum alloy, a molybdenum based metal such as molybdenum (Mo) or a molybdenum alloy, chromium (Cr), tantalum (Ta), neodymium (Nd), titanium (Ti), and iron (Fc).

According to one embodiment of the present disclosure, the light blocking layer 111 may have electrical conductivity. The light blocking layer 111 may be electrically connected to either the source electrode 161 or the drain electrode 162. In some cases, the light blocking layer 111 may be omitted.

A buffer layer 120 is disposed on the light blocking layer 111. The buffer layer 120 covers the upper surface of the substrate 110 and the upper surface of the light blocking layer 111. The buffer layer 120 has insulating property and protects the active layer 130. In some cases, the buffer layer 120 may be omitted.

The active layer 130 is disposed on the substrate 110. Referring to FIG. 2, the active layer 130 may be disposed on the buffer layer 120.

According to one embodiment of the present disclosure, the active layer 130 includes an oxide semiconductor material. According to one embodiment of the present disclosure, the active layer 130 is, for example, an oxide semiconductor layer made of an oxide semiconductor material.

The active layer 130 may include at least one of the oxide semiconductor materials of the IGZO (InGaZnO) based, the IGO (InGaO) based, the IGZTO (InGaZnSnO) based, the GZTO (GaZnSnO) based, the GZO (GaZnO) based, the GO (GaO) based, the TO (SnO) based, the ITO (InSnO) based, and the ITZO (InSnZnO) based. In addition, the active layer 130 may include at least one of the oxide semiconductor materials of the IZO (InZnO) based, the ZO (ZnO) based, the IO (InO) based, the InO (InO) based, the ZnO based, and the FIZO (FelnZnO) based.

The active layer 130 may have a single layer structure, or may have a multilayer structure including two or more oxide semiconductor layers.

According to one embodiment of the present disclosure, the active layer 130 includes a channel part 130n, a source connection part 130a, and a drain connection part 130b.

The channel part 130n overlaps with the gate electrode 150. The channel part 130n has semiconductor characteristics. Depending on the voltage applied to the gate electrode 150, the channel part 130n may have electrical characteristics of a conductor or may have characteristics of an insulator.

The source connection part 130a is connected to one side of the channel part 130n, and the drain connection part 130b is connected to the other side of the channel part 130n. The source connection part 130a and the drain connection part 130b are arranged to be spaced apart from each other, with the channel part 130n interposed therebetween.

According to one embodiment of the present disclosure, the source connection part 130a and the drain connection part 130b do not overlap with the gate electrode 150. The source connection part 130a and the drain connection part 130b may also be referred to as a conductorized portion.

In detail, a source connection part 130a and a drain connection part 130b may be formed by selective conductorization of the active layer 130. For example, the source connection part 130a and the drain connection part 130b may be formed by selectively conductorizing the oxide semiconductor material constituting the active layer 130.

According to one embodiment of the present disclosure, selective conductorization refers to improving the conductivity of a selected portion of the active layer 130 or imparting conductivity to the selected portion. The selectively conductorized portion of the active layer 130 has excellent electrical conductivity and may function as a wiring portion.

According to one embodiment of the present disclosure, selective conductorization may be achieved, for example, by doping a selected region of the active layer 130 with a dopant. In this case, the source connection part 130a and the drain connection part 130b may include a dopant.

According to one embodiment of the present disclosure, doping may be accomplished by ion implantation. Dopant ions may be doped into a selected region of the active layer 130 by ion implantation. According to one embodiment of the present disclosure, the dopant may include at least one of boron (B), phosphorus (P), fluorine (F), and hydrogen (H).

According to one embodiment of the present disclosure, a source connection part 130a and a drain connection part 130b may be formed by doping selected portions of the active layer 130 with a dopant.

However, one embodiment of the present disclosure is not limited thereto, and the source connection part 130a and the drain connection part 130b may be formed by other methods. According to one embodiment of the present disclosure, a selected portion of the active layer 130 may be conductorized by plasma treatment, so that the source connection part 130a and the drain connection part 130b may be formed. For example, during the patterning process of the gate insulating layer 140 or the gate electrode 150, selective conductorization may be performed by plasma treatment, so that the source connection part 130a and the drain connection part 130b may be formed.

According to one embodiment of the present disclosure, the source connection part 130a and the drain connection part 130b each have electrical characteristics similar to those of a conductor. For example, the source connection part 130a and the drain connection part 130b may each have a resistivity of 10⁻⁴ Ωcm or less.

The first protection layer 171 is disposed on the active layer 130. The first protection layer 171 may cover a part of the active layer 130. The first protection layer 171 may contact a part of the channel part 130n and may contact the drain connection part 130b. In addition, a part of the first protection layer 171 overlaps the gate electrode 150. The detailed configuration of the first protection layer 171 will be described later.

A gate insulating layer 140 is disposed on the first protection layer 171. The gate insulating layer 140 may include at least one of silicon oxide and silicon nitride. The gate insulating layer 140 may have a single layer structure or a multilayer structure. In addition, the gate insulating layer 140 may be patterned and disposed only on a part of the active layer 130, or may be disposed to cover the entire active layer 130. The gate insulating layer 140 may also be disposed to cover the entire upper surface of the substrate 110.

The gate electrode 150 is disposed on a gate insulating layer 140. The gate electrode 150 is spaced apart from the active layer 130 and overlaps at least partially with the active layer 130. The gate electrode 150 overlaps with the channel part 130n of the active layer 130.

The gate electrode 150 may include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 150 may also have a multilayer structure including at least two conductive films having different physical properties.

An interlayer insulating layer 181 may be disposed on the gate electrode 150. The interlayer insulating layer 181 is an insulating layer made of an insulating material. In detail, the interlayer insulating layer 181 may be made of an organic material, an inorganic material, or a laminate of an organic material layer and an inorganic material layer.

A source electrode 161 and a drain electrode 162 are disposed on the interlayer insulating layer 181. The source electrode 161 and the drain electrode 162 are spaced apart from each other and are each connected to an active layer 130. The source electrode 161 and the drain electrode 162 may each be connected to an active layer 130 through a contact hole penetrating the interlayer insulating layer 181.

The source electrode 161 and the drain electrode 162 may each include at least one of molybdenum (Mo), aluminum (Al), chromium (Cr), gold (Au), titanium (Ti), nickel (Ni), neodymium (Nd), copper (Cu), and alloys thereof. The source electrode 161 and the drain electrode 162 may each be formed of a single layer made of a metal or an alloy of metals, or may be formed of multilayer structure having two or more layers.

Hereinafter, the first protection layer 171 is described in more detail.

The first protection layer 171 is disposed on a portion of the channel part 130n to protect the channel part 130n. In addition, the first protection layer 171 is disposed on the drain connection part 130b to protect the drain connection part 130b.

Referring to FIG. 1, the first protection layer 171 may be integrally formed on the upper surface UPS1 of a portion of the channel part 130n and on the upper surface UPS2 of the drain connection part 130b. According to one embodiment of the present disclosure, the first protection layer 171 contacts the upper surface UPS1 of a portion of the channel part 130n and the upper surface UPS2 of the drain connection part 130b.

Referring to FIGS. 1 and 3, the first protection layer 171 contacts the side surfaces TS1, TS2, TS3 of the active layer 130. In detail, the first protection layer 171 contacts the side surfaces TS1, TS2 of the channel part 130n and the side surfaces TS1, TS2, TS3 of the drain connection part 130b. As a result, the first protection layer 171 may protect the side surfaces of the channel part 130n and the side surfaces of the drain connection part 130b.

According to one embodiment of the present disclosure, the upper surface of the active layer 130 may be referred to as the surface of the active layer 130 facing in the opposite direction to the substrate 110. The surface of the active layer 130 facing the substrate 110 may be referred to as the lower surface. The side surfaces TS1, TS2, TS3 of the active layer 130 refer to the surface of the active layer 130 between the upper surface and the lower surface.

During the formation of the active layer 130, the active layer 130 contacts an etchant or an etching gas. The side surfaces TS1, TS2, TS3 of the active layer 130 that have contacted with the etchant or etching gas may be damaged by the etchant or etching gas.

Defects may occur on the side surfaces TS1, TS2, TS3 of the active layer 130 that have been exposed to the etching solution or etching gas. For example, the side surface TS1, TS2, TS3 of the active layer 130 that is in contact with the etchant or etching gas may have a defect such as an elemental deficiency. In the part where the defect occurs, it is difficult to form a stable chemical bonding, and the physical structure may be unstable.

In addition, atomic migration may occur in the part where the defect has occurred, and such elemental migration may cause metal void, which is a loss of metal atom. Areas with metal voids are easily damaged by stress, and their physical structures may be easily destroyed.

As described above, the side surfaces TS1, TS2, TS3 of the active layer 130 that have been in contact with the etchant or etching gas are vulnerable to impact or stress. For example, when a carrier having a large kinetic energy moves through the side surfaces TS1, TS2, TS3 of the active layer 130 that are damaged by the etchant or etching gas, the carrier may be trapped at a defect portion. When a carrier having a large kinetic energy is trapped at a defect portion of the active layer 130, the defect portion becomes unstable and the side surfaces TS1, TS2, TS3 of the active layer 130 may be damaged further. As a result, the stability of the active layer 130 may be deteriorated.

In a thin film transistor 100 using an oxide semiconductor material, a high voltage is applied to a drain connection part 130b. Accordingly, a strong electric field, a strong horizontal electric field, may be applied to the drain connection part 130b. In the channel part 130n, since a relatively high horizontal electric field is applied at the portion near the drain connection part 130b, carriers may be accelerated at the drain connection part 130b side of the channel part 130n, and thus hot carriers having high energy may be formed. These hot carriers may damage the channel part 130n and the drain connection part 130b. In one embodiment of the present disclosure, “drain connection part 130b side of the channel part 130n” means a portion of channel part 130n near the drain connection part 130b, which can correspond to, for example, the area designated by “L1” of FIG. 2.

In particular, in a state that the side of the drain connection part 130b to which a strong electric field is applied is defective, the side of the drain connection part 130b may be easily damaged when the thin film transistor 100 is driven or operated for a long time.

According to one embodiment of the present disclosure, the first protection layer 171 may protect the upper surface and side surfaces TS1, TS2, TS3 of the active layer 130 damaged by an etchant or an etching gas. The first protection layer 171 is disposed on the drain connection part 130b side of the channel part 130n, and thereby protects the channel part 130n and the drain connection part 130b of the active layer 130.

According to one embodiment of the present disclosure, the first protection layer 171 has a higher oxygen concentration than the active layer 130 and is formed as a chemically stable layer.

In addition, the first protection layer 171 may include the same metal as the active layer 130. Therefore, the interface characteristics between the first protection layer 171 and the active layer 130 are excellent, and the bonding or adhesion characteristics between the first protection layer 171 and the active layer 130 are excellent. In addition, the element included in the first protection layer 171 may play a role in filling a defect site on the side of the active layer 130. As a result, the defect that occurred on the side of the active layer 130 may be cured by the first protection layer 171.

For example, according to one embodiment of the present disclosure, the active layer 130 and the first protection layer 171 may include at least one same metal atom. The metal element included in the first protection layer 171 may replace a defective element of the active layer 130. Alternatively, the metal element included in the first protection layer 171 may be shared between the first protection layer 171 and active layer 130 at a defective portion of the active layer 130. Accordingly, a defect on the side of the active layer 130 may be cured, and the stability of the active layer 130 may be improved.

The first protection layer 171 may include an oxide semiconductor material.

According to one embodiment of the present disclosure, the first protection layer 171 may include at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, and a GO (GaO) based oxide semiconductor material.

Additionally, the first protection layer 171 may include at least one of a TO (SnO) based, ITO (InSnO) based, and ITZO (InSnZnO) based oxide semiconductor material.

According to one embodiment of the present disclosure, the first protection layer 171 may include gallium (Ga). In addition, the first protection layer 171 may include tin (Sn). Gallium (Ga) and tin (Sn) may form a stable bond with oxygen. Therefore, the first protection layer 171 including at least one of gallium (Ga) and tin (Sn) may have excellent chemical stability and effectively protect the channel part 130n and the drain connection part 130b.

The first protection layer 171 may have a metal composition identical to or similar to that of the active layer 130. Therefore, the first protection layer 171 and the active layer 130 have excellent interface characteristics, and the stability of the surface of the active layer 130 may be improved.

According to one embodiment of the present disclosure, both the active layer 130 and the first protection layer 171 may include gallium (Ga). The gallium (Ga) concentration of the first protection layer 171 may be higher than the gallium (Ga) concentration of the active layer 130.

Here, the gallium (Ga) concentration of the first protection layer 171 may be calculated as the atomic % (at %), which is a ratio of the number of gallium (Ga) atoms to the total number of atoms of the first protection layer 171. In addition, the gallium (Ga) concentration of the active layer 130 may be calculated as the atomic % (at %), which is a ratio of the number of gallium (Ga) atoms to the total number of atoms of the active layer 130.

The first protection layer 171 according to one embodiment of the present disclosure includes an oxide semiconductor material, but has electrical characteristics close to those of an insulating layer.

According to one embodiment of the present disclosure, the first protection layer 171 may not have a role in the carrier movement of the active layer 130. The first protection layer 171 is disposed to improve the stability of the active layer 130 and the thin film transistor 100.

According to one embodiment of the present disclosure, the first protection layer 171 has a resistivity higher than a resistivity of the active layer 130. In detail, the first protection layer 171 has a resistivity greater than that of the drain connection part 130b and a resistivity greater than that of the channel part 130n.

Additionally, in order not to affect the electrical characteristics of the active layer 130, the first protection layer 171 has a thin thickness.

When the resistivity of the first protection layer 171 is less than 1.0×10⁶ Ω·cm, carriers may move through the first protection layer 171. When carriers move through the first protection layer 171, the electrical characteristics of the channel part 130n and the active layer 130 may change, and difficulties may arise in designing the active layer 130.

Therefore, according to one embodiment of the present disclosure, the first protection layer 171 may have a resistivity of 1.0×10⁶ Ω·cm or more. The first protection layer 171 may not have conductivity. According to one embodiment of the present disclosure, the first protection layer 171 may have a resistivity of 1.0×10⁶ Ω·cm or more, and thus the first protection layer 171 does not have a role in the carrier movement of the active layer 130, and does not affect the electrical characteristics of the active layer 130.

The first protection layer 171 according to one embodiment of the present disclosure has a low carrier concentration. According to one embodiment of the present disclosure, the first protection layer 171 has a carrier concentration lower than a carrier concentration of the active layer 130.

According to one embodiment of the present disclosure, the first protection layer 171 may have a carrier concentration of 1.0×10¹⁶ ea/cm³ or less. The active layer 130 may have a carrier concentration of 1.0×10¹⁷ ea/cm³ or more. In detail, the channel part 130n may have a carrier concentration of 1.0×10¹⁷ ea/cm³ or more. The channel part 130n may have a carrier concentration of 1.0×10¹⁷ ea/cm³ or more when the thin film transistor 100 is turned off.

When the first protection layer 171 has a carrier concentration of 1.0×10¹⁶ ea/cm³ or less, the first protection layer 171 may function as an insulating layer and a protection layer.

According to one embodiment of the present disclosure, the first protection layer 171 has a higher resistivity and lower carrier concentration than the active layer 130, so that even if the thin film transistor 100 is turned on, the first protection layer 171 may not affect the ON current characteristics of the thin film transistor 100.

According to one embodiment of the present disclosure, the first protection layer 171 may have a mobility of 2 cm²/V·s or less. In detail, the first protection layer 171 may have a mobility of 1.5 cm²/V·s or less, and may also have a mobility of 1 cm²/V·s or less.

According to one embodiment of the present disclosure, the first protection layer 171 has a higher oxygen concentration than the active layer 130. By increasing the oxygen partial pressure in the manufacturing step of the first protection layer 171, the oxygen concentration of the first protection layer 171 may be increased.

For example, when the first protection layer 171 is formed, the oxygen partial pressure may be set to 50% or more. In detail, the first protection layer 171 may be formed by deposition or ALD under a condition that the oxygen partial pressure is 50% to 75%.

Since the first protection layer 171 has a higher oxygen concentration than the active layer 130, the first protection layer 171 may have excellent chemical stability and have a higher resistivity than the active layer 130.

According to one embodiment of the present disclosure, the first protection layer 171 is chemically stable. The first protection layer 171 may block or capture oxygen (O) or hydrogen (H). In detail, the first protection layer 171 having excellent chemical stability may protect the active layer 130 and the channel part 130n from hydrogen (H).

According to one embodiment of the present disclosure, the first protection layer 171 includes metal atoms and oxygen atoms. The total number of oxygen atoms included in the first protection layer 171 may be 1.5 to 2.5 times the total number of metal atoms. According to one embodiment of the present disclosure, in a state that the first protection layer 171 includes 1.5 to 2.5 times as much oxygen atoms as the number of metal atoms, the metals included in the first protection layer 171 may form a stable stoichiometric bond with oxygen.

For example, the first protection layer 171 including indium (In), zinc (Zn), gallium (Ga), and tin (Sn) as metal atoms may be described as follows. Generally, each of indium (In), zinc (Zn), gallium (Ga), and tin (Sn) may combine with oxygen to form In₂O₃, ZnO, ZnO₂, GaO, Ga₂O₃, GaO₂, and SnO₂, or the like. Considering the stoichiometry of indium (In), zinc (Zn), gallium (Ga), and tin (Sn) with oxygen, when the first protection layer 171 includes 1.5 to 2.5 times as much oxygen atoms as the number of metal atoms, the metals included in the first protection layer 171 may form a stoichiometrically stable bond with oxygen. As a result, the first protection layer 171 may have excellent chemical stability.

In addition, the first protection layer 171 has insulating property and has electrical and chemical properties similar to those of an insulator, so that the first protection layer 171 may have a strong bond with the gate insulating layer 140, and the first protection layer 171 may maintain the strong bond with the gate insulating layer 140. The first protection layer 171 is disposed between the active layer 130 and the gate insulating layer 140, and may act as an intermediate that prevents a rapid change in the properties of the material. The first protection layer 171 may act as an interfacial layer between the active layer 130 and the gate insulating layer 140. Accordingly, it may be prevented that a defect occurs between the active layer 130 and the gate insulating layer 140 due to a difference in properties of the materials.

According to one embodiment of the present disclosure, the first protection layer 171 may cure a defect on the surface of the active layer 130, block hydrogen, and prevent a defect from occurring between the active layer 130 and the gate insulating layer 140.

In addition, the first protection layer 171 according to one embodiment of the present disclosure may block damage and stress applied to the drain connection part 130b of the active layer 130 during the manufacturing process of thin film transistor 100. For example, by disposing the first protection layer 171 on the drain connection part 130b of the active layer 130, the drain connection part 130b of the active layer 130 may be prevented from being damaged or contaminated during the etching process or the strip process. As a result, the stability of the active layer 130 may be improved.

The first protection layer 171 may have a thinner thickness than the active layer 130.

The first protection layer 171 according to one embodiment of the present disclosure may be designed to have high electrical resistance and a thin thickness, so that the first protection layer 171 may not directly affect the electrical characteristics of the active layer 130. As a result, even though the first protection layer 171 is disposed on the active layer 130, the mobility or carrier concentration of the active layer 130 may not be substantially changed by the first protection layer 171. Accordingly, the first protection layer 171 may not affect the operating characteristics of the thin film transistor 100.

According to one embodiment of the present disclosure, in order to block damage and stress applied to the active layer 130 without affecting the electrical characteristics of the active layer 130, the first protection layer 171 may have a thickness of 3 nm or less.

In detail, according to one embodiment of the present disclosure, the first protection layer 171 may have a thickness of 0.5 to 3 nm.

When the thickness of the first protection layer 171 is less than 0.5 nm, the first protection layer 171 may not sufficiently protect the active layer 130 due to the thin thickness. In addition, when the thickness of the first protection layer 171 is designed to be less than 0.5 nm, the first protection layer 171 may be easily damaged due to the thin thickness, and the mechanical stability may be deteriorated. Therefore, according to one embodiment of the present disclosure, the thickness of the first protection layer 171 may be designed to be 0.5 nm or more.

Although the first protection layer 171 has high resistivity, if the thickness of the first protection layer 171 increases, there is a possibility that charge flow through the first protection layer 171 may occur. If the thickness of the first protection layer 171 increases, for example, there is a possibility that an electron-hole pair may be formed in the first protection layer 171 so that the first protection layer 171 may exhibit semiconductor characteristics. If the first protection layer 171 has semiconductor characteristics, it may not be easy to control the electric property of the thin film transistor 100.

If the thickness of the first protection layer 171 exceeds 3 nm, the first protection layer 171 may have semiconductor characteristics, which may cause variables in carrier movement, and thus it may not be easy to control the electrical characteristics of the thin film transistor 100. In detail, if the thickness of the first protection layer 171 exceeds 3 nm, electron-hole pairs may be formed in the first protection layer 171, or semiconductor characteristics may occur in the first protection layer 171, which may change the threshold voltage or switching characteristics of the thin film transistor 100, and electrical stability of the thin film transistor 100 may be deteriorated.

Therefore, according to one embodiment of the present disclosure, the thickness of the first protection layer 171 may be designed to be 3 nm or less.

In detail, the first protection layer 171 may have a thickness of 1 to 3 nm. When the thickness of the first protection layer 171 is 1 nm or more, the first protection layer 171 may protect the active layer 130 more efficiently. In addition, when the thickness of the first protection layer 171 is 3 nm or less, the first protection layer 171 may have no or little effect on the electrical characteristics of the active layer 130. According to one embodiment of the present disclosure, the first protection layer 171 may have a thickness of, for example, 1.0 to 2.5 nm or 1.5 to 2.5 nm.

Referring to FIGS. 1 and 2, the first protection layer 171 covers the channel part 130n of the active layer 130 and covers the drain connection part 130b, which is a conductorized region. The first protection layer 171 has higher resistivity and lower mobility than the active layer 130, and is not sensitive to factors affecting the stability of the thin film transistor 100 compared to the channel part 130n. Therefore, even if external factors affecting the electrical characteristics of the thin film transistor 100, such as oxygen O or hydrogen H, penetrate into the first protection layer 171, the electrical characteristics of the first protection layer 171 do not change significantly. In this way, the first protection layer 171 serves to protect the active layer 130 from external factors. As a result, the electrical stability of the active layer 130 may be improved due to the first protection layer 171.

The first protection layer 171 may be disposed on a portion of the channel part 130n. Referring to FIGS. 1 and 2, the first protection layer 171 is disposed on the drain connection part 130b side of the channel part 130n. The first protection layer 171 may be disposed on a portion of less than half of the area of the channel part 130n.

In detail, the first protection layer 171 is placed in a portion of less than half of the area of the channel part 130n, with a condition that the first protection layer 171 may be disposed on channel part 130n only in the area near the drain connection part 130b, which can be seen from L1 of FIG. 2. Referring to FIGS. 1 and 2, an overlapping length L1 of the first protection layer 171 and the channel part 130n is located in a portion of the channel part 130n near the drain connection part 130b. The portion of channel part 130n corresponding to “L1” of FIG. 2 may be referred to as a drain connection part 130b side of the channel part 130n.

According to one embodiment of the present disclosure, the overlapping length L1 of the first protection layer 171 and the channel part 130n may be designed to be less than or equal to half Lin of the length L_{ch} of the channel part 130n. Here, the length L_{ch} of the channel part 130n is defined as the distance between the source connection part 130a and the drain connection part 130b. In addition, the overlapping length L1 of the first protection layer 171 and the channel part 130n is measured along a direction parallel to a line connecting the source connection part 130a and the drain connection part 130b.

According to one embodiment of the present disclosure, the first protection layer 171 is disposed on the drain connection part 130b side of the channel part 130n of the active layer 130, thereby improving the stability of the channel part 130n located at the drain connection part 130b side. Since the first protection layer 171 is disposed on the drain connection part 130b side of the channel part 130n, the drain connection part 130b side of the channel part 130n may have a lower carrier concentration than the source connection part 130a side of the channel part 130n. In one embodiment of the present disclosure, “source connection part 130a side of the channel part 130n” means a portion of channel part 130n near the source connection part 130a.

A high horizontal electric field is applied to the drain connection part 130b side of the channel part 130n, and the electric shock on the drain connection part 130b side is large. Therefore, according to one embodiment of the present disclosure, even though the carrier concentration on the drain connection part 130b side of the channel part 130n is lowered, the stability on the drain connection part 130b side is improved by disposing the first protection layer 171 on the drain connection part 130b side of the channel part 130n.

On the other hand, since carrier loss may occur due to the first protection layer 171, the first protection layer 171 is not disposed on the source connection part 130a side of the channel part 130n.

In a thin film transistor 100 according to one embodiment of the present disclosure, the threshold voltage Vth, the amount of current, and the s-factor which refers to the sub-threshold swing are mainly determined at the source electrode 161 and the source connection part 130a side of the channel part 130n. In addition, a relatively lower horizontal electric field is applied to the source connection part 130a side compared to the drain connection part 130b side, and a relatively small electric shock occurs at the source connection part 130a side of the channel part 130n.

Therefore, according to one embodiment of the present disclosure, the first protection layer 171 is not disposed on the source connection part 130a side of the channel part 130n, thereby preventing carrier loss from being generated at the source connection part 130a side.

In a thin film transistor 100 according to one embodiment of the present disclosure, a first protection layer 171 is not disposed on the source connection part 130a side of the channel part 130n, and the source connection part 130a side of the channel part 130n may have a high carrier concentration and excellent current characteristics.

According to one embodiment of the present disclosure, the first protection layer 171 is not disposed in half of the area of the channel part 130n disposed toward the source connection part 130a.

According to one embodiment of the present disclosure, the length of the region where the first protection layer 171 and the channel part 130n do not overlap may be designed to be at least ½ of the length L_{ch} of the channel part 130n (≥L_{1/2}). According to one embodiment of the present disclosure, the region where the first protection layer 171 and the channel part 130n do not overlap is disposed on the source connection part 130a side of the region of the channel part 130n.

According to one embodiment of the present disclosure, the first protection layer 171 may be disposed on the drain connection part 130b and may have a shape that extends toward the channel part 130n.

According to one embodiment of the present disclosure, the overlapping length L1 of the first protection layer 171 and the channel part 130n may be set to 0.5 μm or more. If the overlapping length L1 of the first protection layer 171 and the channel part 130n is less than 0.5 μm, the channel part 130n may not be sufficiently protected by the first protection layer 171.

When the overlapping length L1 of the first protection layer 171 and the channel part 130n is 0.5 μm or more, the channel part 130n at the drain connection part 130b side may be stably protected by the first protection layer 171.

The source connection part 130a and the drain connection part 130b illustrated in the drawing are distinguished only for the convenience of explanation, and the source connection part 130a and the drain connection part 130b may be interchanged. The source connection part 130a illustrated in the drawing may become the drain connection part, and the drain connection part 130b may become the source connection part.

According to one embodiment of the present disclosure, the source connection part 130a may serve as either a source electrode or a drain electrode. In addition, the drain connection part 130b may serve as either a drain electrode or a source electrode.

FIG. 4 is a cross-sectional view of a thin film transistor 200 according to another embodiment of the present disclosure. Hereinafter, to avoid redundancy, descriptions of components already described are omitted or components already described are briefly described.

Referring to FIG. 4, the gate insulating layer 140 may have a patterned shape. For example, the gate insulating layer 140 may be patterned into a shape corresponding to the shape of the gate electrode 150.

The gate insulating layer 140 and the gate electrode 150 may be patterned in one process. During the patterning process of the gate insulating layer 140 and the gate electrode 150, selective conductorization may be achieved, so that the source connection part 130a and the drain connection part 130b may be formed. For example, during the patterning process of the gate insulating layer 140 and the gate electrode 150, selective conductorization may be achieved in a plasma treatment process, so that the source connection part 130a and the drain connection part 130b may be formed.

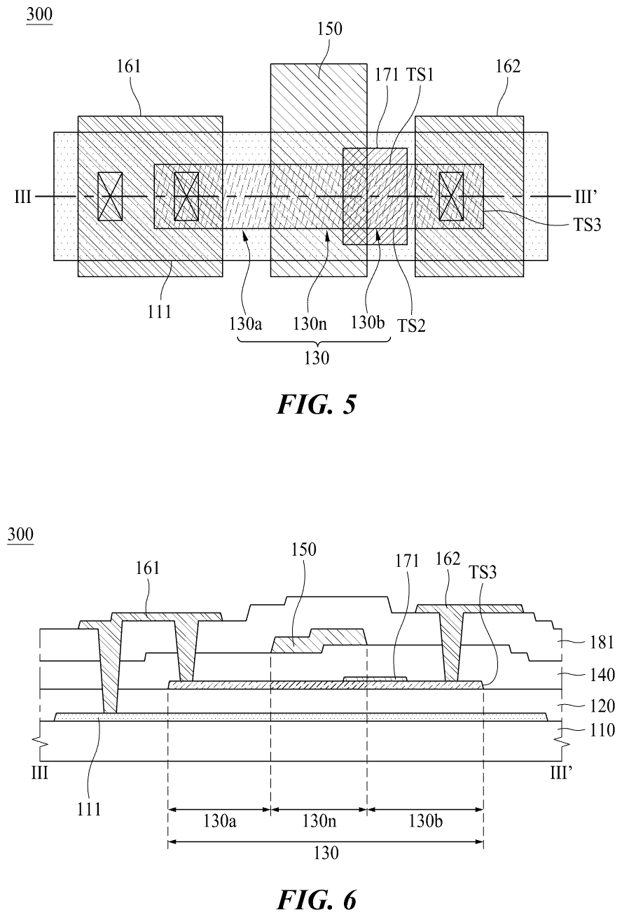

FIG. 5 is a plan view of a thin film transistor 300 according to another embodiment of the present disclosure, and FIG. 6 is a cross-sectional view taken along line III-III′ of FIG. 5.

According to another embodiment of the present disclosure, the first protection layer 171 may be disposed on a portion of the drain connection part 130b.

Referring to FIGS. 5 and 6, the first protection layer 171 may be disposed only at and around the borderline between the channel part 130n and the drain connection part 130b. In detail, in the drain connection part 130b, the first protection layer 171 may be disposed only at the region connected to the channel part 130n and the surrounding area thereof. Referring to FIGS. 5 and 6, the first protection layer 171 may not be disposed in the contact portion where the drain electrode 162 and the drain connection part 130b contact and the surrounding area thereof in the drain connection part 130b.

If the first protection layer 171 is not disposed on the contact portion where the drain electrode 162 and the drain connection part 130b contact, and the drain electrode 162 is in direct contact with the drain connection part 130b, the electrical contact characteristics may be improved.

Referring to FIG. 5, the first protection layer 171 may be integrally formed on the upper part of a part of the channel part 130n and the upper part of a part of the drain connection part 130b. The first protection layer 171 contacts the upper surface of a part of the channel part 130n and the upper surface of a part of the drain connection part 130b.

Referring to FIG. 5, the first protection layer 171 contacts the side surfaces TS1, TS2 of the active layer 130. In detail, among the side surfaces TS1, TS2, TS3 of the active layer 130, the side surfaces TS1, TS2 in the length direction may contact the first protection layer 171. According to one embodiment of the present disclosure, among the side surfaces of the drain connection part 130b, the side surface TS3 in the width direction may not contact the first protection layer 171.

The first protection layer 171 contacting the side surface of the channel part 130n and the side surface of the drain connection part 130b may protect the side surface of the channel part 130n and the side surface of the drain connection part 130b.

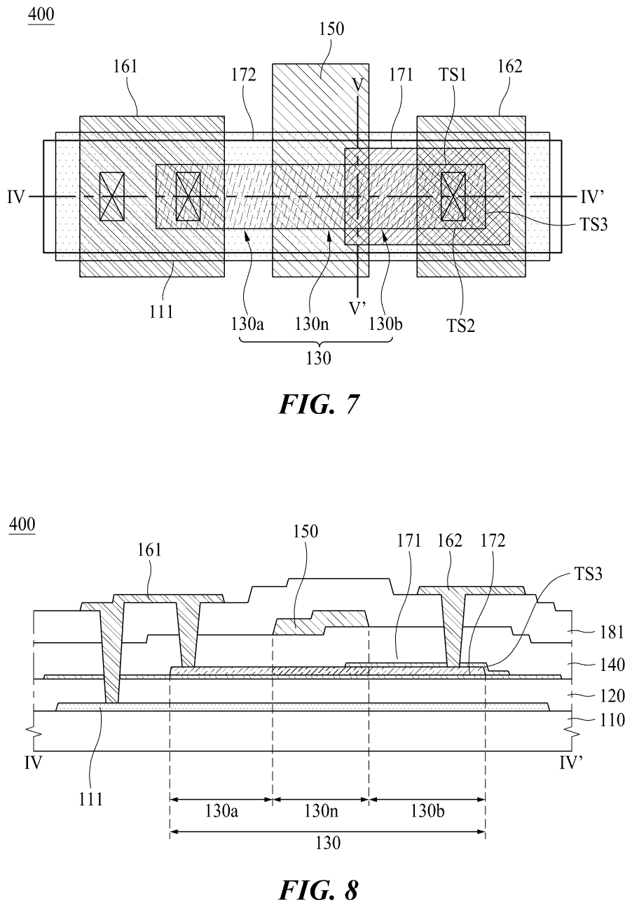

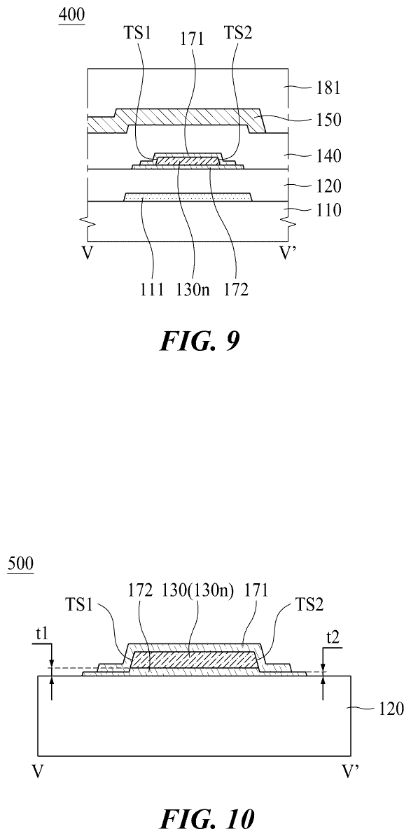

FIG. 7 is a plan view of a thin film transistor 400 according to another embodiment of the present disclosure, FIG. 8 is a cross-sectional view taken along line IV-IV′ of FIG. 7, and FIG. 9 is a cross-sectional view taken along line V-V′ of FIG. 7.

A thin film transistor 400 according to another embodiment of the present disclosure further includes a second protection layer 172. The second protection layer 172 contacts the active layer 130. The active layer 130 may be disposed on the second protection layer 172.

Referring to FIGS. 7 and 8, a first protection layer 171 may be disposed on the upper surface of the active layer 130, and a second protection layer 172 may be disposed on the lower surface of the active layer 130. The active layer 130 may be disposed between the first protection layer 171 and the second protection layer 172.

According to another embodiment of the present disclosure, at least a portion of the first protection layer 171 may contact the second protection layer 172. Referring to FIGS. 7, 8, and 9, the first protection layer 171 may extend to the side surfaces TS1, TS2 of the channel part 130n and the side surfaces TS1, TS2, TS3 of the drain connection part 130b to contact the second protection layer 172.

According to another embodiment of the present disclosure, the upper surface, lower surface, and three side surfaces TS1, TS2, TS3 of the drain connection part 130b may be surrounded and protected by the first protection layer 171 and the second protection layer 172. In addition, the upper surface, lower surface, and two side surfaces TS1, TS2 of the channel part 130n may be surrounded and protected by the first protection layer 171 and the second protection layer 172.

The second protection layer 172 may have a metal composition identical to or similar to that of the active layer 130. According to another embodiment of the present disclosure, the second protection layer 172 includes an oxide semiconductor material, but has electrical property close to those of an insulating layer.

The second protection layer 172 may have the same composition as the first protection layer 171, or may have a different composition.

The second protection layer 172 may include at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, a GO (GaO) based oxide semiconductor material, a TO (SnO) based oxide semiconductor material, an ITO (InSnO) based oxide semiconductor material, and an ITZO (InSnZnO) oxide semiconductor material.

According to another embodiment of the present disclosure, the second protection layer 172 may include at least one of gallium (Ga) and tin (Sn). The gallium (Ga) concentration of the second protection layer 172 may be designed to be higher than the gallium (Ga) concentration of the active layer 130.

According to another embodiment of the present disclosure, the second protection layer 172 has a resistivity greater than that of the active layer 130. In detail, the second protection layer 172 has a resistivity greater than that of the drain connection part 130b and a resistivity greater than that of the channel part 130n.

According to one embodiment of the present disclosure, the second protection layer 172 does not participate in the carrier movement of the active layer 130. The second protection layer 172 is disposed to improve the electrical stability of the active layer 130 and the thin film transistor 100.

The second protection layer 172 may have a lower carrier concentration than the active layer 130n and may have a higher oxygen concentration than the active layer 130n.

The second protection layer 172 may have a resistivity of 1.0×10⁶ Ω·cm or more.

When a carrier moves through the second protection layer 172, the electrical characteristics of the channel part 130n and the active layer 130 may vary, and the design of the active layer 130 may be difficult. In order to prevent the second protection layer 172 from being conductive, according to another embodiment of the present disclosure, the resistivity of the second protection layer 172 may be designed to be 1.0×10⁶ Ω·cm or more.

The second protection layer 172 may block or capture oxygen (O) or hydrogen (H). The second protection layer 172 has excellent chemical stability and may have a role in protecting the active layer 130 and the channel part 130n from hydrogen (H).

The second protection layer 172 may protect the channel part 130n from hydrogen (H) incident, particularly, from the lower surface of the active layer 130.

In order to protect the active layer 130 and the channel part 130n while not having semiconductor property or electrical conductivity, the second protection layer 172 may have a thickness of 0.5 to 3 nm.

The second protection layer 172 may have the same thickness as the first protection layer 171 or may have a different thickness.

In a plan view, the second protection layer 172 may have a larger area than the active layer 130. The second protection layer 172 may cover the entire lower surface of the active layer 130. The second protection layer 172 covers the entire lower surface of the active layer 130 and may have a larger area than the lower surface of the active layer 130.

On the outside of the lower surface of the active layer 130, the second protection layer 172 may contact the first protection layer 171.

The second protection layer 172 may have a first region overlapping the active layer 130 and a second region not overlapping the active layer 130. The first region and the second region of the second protection layer 172 may have the same thickness or may have different thicknesses.

According to another embodiment of the present disclosure, the second protection layer 172 may contact the first protection layer 171 in the second region.

FIG. 10 is an enlarged cross-sectional view of a portion of a thin film transistor 500 according to another embodiment of the present disclosure.

FIG. 10 is a cross-sectional view corresponding to the cross-sectional view taken along line V-V′ of FIG. 7. Note that in this cross-sectional view, the active layer 130 is also labeled for case of description, in addition to the channel part 130n which is a part of the active layer 130.

According to another embodiment of the present disclosure, the active layer 130 is formed after the second protection layer 172 is formed, and the first protection layer 171 is formed after the active layer 130 is formed.

The active layer 130 and the first protection layer 171 are patterned. During the patterning process of the active layer 130 and the first protection layer 171, a portion of the second protection layer 172 that does not overlap the active layer 130 may be additionally etched.

The second region of the second protection layer 172 that does not overlap with the active layer 130 may be exposed to etching twice or more. In the second protection layer 172, the thickness of the second region t2 that does not overlap with the active layer 130 may be smaller than the thickness of the first region t1 that overlaps with the active layer 130 (t1>t2).

Therefore, according to one embodiment of the present disclosure, the first region may have a greater thickness than the second region (t1>t2).

In one embodiment of the present disclosure, there is no particular limitation in the ratio of the thickness of the first region t1 to the thickness of the second region t2. According to one embodiment of the present disclosure, the first region and the second region may have a thickness ratio of 1:0.3 to 1:0.9 (t1:t2=1:0.3 to 0.9). According to one embodiment of the present disclosure, the second region of the second protection layer 172 may have a thickness (t2) of about 30% to 90% of the thickness (t1) of the first region. However, one embodiment of the present disclosure is not limited thereto.

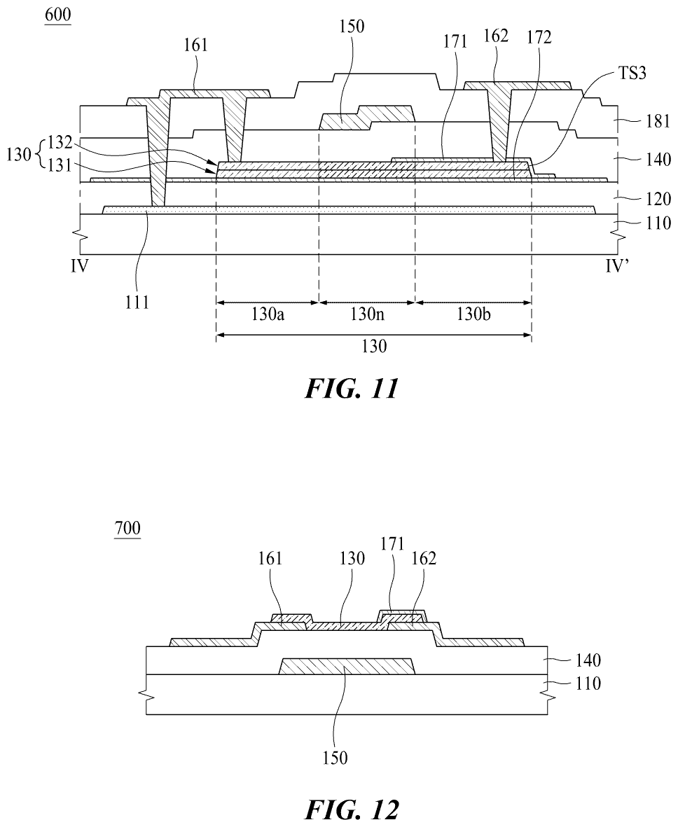

FIG. 11 is a cross-sectional view of a thin film transistor 600 according to another embodiment of the present disclosure.

Referring to FIG. 11, the active layer 130 may include a first oxide semiconductor layer 131 and a second oxide semiconductor layer 132 on the first oxide semiconductor layer 131.

The first oxide semiconductor layer 131 may serve as a support layer supporting the second oxide semiconductor layer 132. The second oxide semiconductor layer 132 may serve as a main channel layer.

The first oxide semiconductor layer 131 serving as a support layer may have excellent film stability and mechanical stability. The first oxide semiconductor layer 131 may include, for example, at least one of an IGZO (InGaZnO) based, IGO (InGaO) based, IGZTO (InGaZnSnO) based, GZTO (GaZnSnO) based, GZO (GaZnO) based, and GO (GaO) based oxide semiconductor material. However, one embodiment of the present disclosure is not limited thereto, and the first oxide semiconductor layer 131 may be made of other oxide semiconductor materials known in the art.

As shown in FIG. 11, when a second protection layer 172 is disposed under the active layer 130, the first oxide semiconductor layer 131 may include the same kind of metal as the second protection layer 172.

The second oxide semiconductor layer 132 may be made of, for example, an oxide semiconductor material such as an IZO (InZnO) based material, a FIZO (FelnZnO) based material, a TO (SnO) based material, an IGO (InGaO) based material, an ITO (InSnO) based material, an IGZO (InGaZnO) based material, an IGZTO (InGaZnSnO) based material, a GZTO (GaZnSnO) based material, an ITZO (InSnZnO) based material, or an IO (InO) based material. For example, the second oxide semiconductor layer 132 may include a FIZO (FelnZnO) based oxide semiconductor material. However, one embodiment of the present disclosure is not limited thereto, and the second oxide semiconductor layer 132 may be made of other oxide semiconductor materials known in the art.

The second oxide semiconductor layer 132 may include the same kind of metal as the first protection layer 171.

FIG. 12 is a cross-sectional view of a thin film transistor 700 according to another embodiment of the present disclosure.

Referring to FIG. 12, a thin film transistor 700 according to another embodiment of the present disclosure includes a gate electrode 150 on a substrate 110, a gate insulating layer 140 on the gate electrode 150, and an active layer 130 on the gate insulating layer 140. In addition, the thin film transistor 700 according to another embodiment of the present disclosure may include a source electrode 161 and a drain electrode 162 disposed on the gate insulating layer 140. The source electrode 161 and the drain electrode 162 are spaced apart from each other and each contacts the active layer 130.

Referring to FIG. 12, a first protection layer 171 may be disposed on the active layer 130. In detail, the first protection layer 171 may be disposed on a portion of the channel part. In FIG. 12, the channel part of the active layer 130 may be defined as a region that overlaps the gate electrode 150 but does not overlap the source electrode 161 and the drain electrode 162.

In addition, the first protection layer 171 may be disposed on an area overlapping the drain electrode 162 of the active layer 130.

The first protection layer 171 may contact the side surface of the channel part. In addition, the first protection layer 171 may contact the side surface of the active layer 130 at the region overlapping the drain electrode 162.

The first protection layer 171 may protect the drain electrode 162 side of the channel part and the region of the active layer 130 that overlaps the drain electrode 162.

As shown in FIG. 12, a thin film transistor in which the gate electrode 150 is positioned below the active layer 130 is called a thin film transistor having a bottom gate structure. On the other hand, a thin film transistor in which the gate electrode 150 is disposed above the active layer 130 as shown in FIGS. 2, 4, 6, 8, and 11 is called a thin film transistor having a top gate structure.

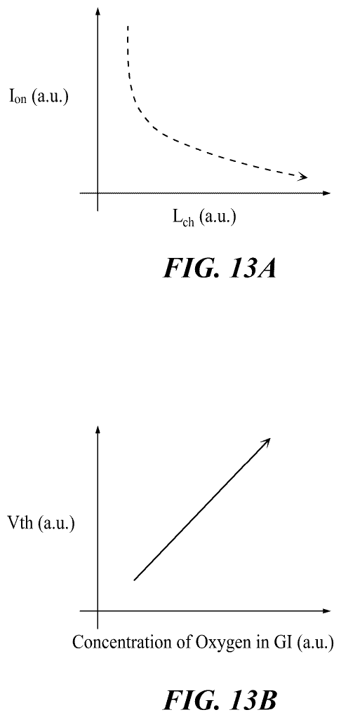

FIG. 13A is a graph explaining the relationship between the channel length L_{ch} and the drain current Iₒₙ, and FIG. 13B is a graph explaining the relationship between the oxygen content of the gate insulating layer 140 (GI) and the threshold voltage (Vth).

When the thin film transistor is operated for a long time, heat generation may occur in the drain region or the drain connection part 130b. For example, Joule heating may occur in the drain connection part 130b, and the amount of heat P may be calculated as “P=I²R”. In addition, carriers having high kinetic energy (hot carriers) are generated due to a strong horizontal electric field applied to the drain connection part 130b, and when these carriers (hot carriers) are trapped in a defect portion of the active layer 130, electrical deterioration may occur. The defect portion of the active layer 130 may be generated, for example, during an etching process for the active layer 130. Defects in the active layer 130 may be significantly generated at the side surfaces TS1, TS2, TS3 of the active layer 130, which are portions of the active layer 130 that contact the etchant.

When a carrier with high kinetic energy collides with a defect portion of the active layer 130, the active layer 130 may be damaged.

In order to prevent damage to the active layer 130 caused by carriers with high kinetic energy and to prevent electrical deterioration of the active layer 130, there is a method of increasing the length of the channel part 130n.

The total horizontal electric field E applied to the channel part 130n may be calculated as “E=V_{DS}/L_{ch}”, where V_{DS} is a voltage between the source connection part 130a and the drain connection part 130b, and L_{ch} is a length of the channel part 130n. When the length of the channel part 130n increases, the total horizontal electric field applied to the channel part 130n decreases. When the total horizontal electric field applied to the channel part 130n decreases, the kinetic energy of carriers decreases, and the number of carriers having high kinetic energy may decrease. As a result, damage to the active layer 130 by carriers having high kinetic energy may be suppressed or reduced, and electrical deterioration of the active layer 130 may be reduced.

However, as illustrated in FIG. 13A, when the length L_{ch} of the channel part 130n increases, the drain current Iₒₙ may decrease. Therefore, it is necessary to prevent damage to the active layer 130 and the channel part 130n without a significant decrease in the drain current Iₒₙ.

Meanwhile, in order to prevent damage to the active layer 130 and the channel part 130n, there is a method of reducing the oxygen concentration of the gate insulating layer 140. When the oxygen concentration of the gate insulating layer 140 is reduced, the carrier trap concentration is reduced, so that damage to the active layer 130 and the channel part 130n may be suppressed.

However, as illustrated in FIG. 13B, there is a problem that the threshold voltage Vth decreases when the oxygen concentration of the gate insulating layer 140 (GI) decreases. When the threshold voltage Vth of the thin film transistor decreases, the NBTIS (negative bias temperature illumination stress) characteristic deteriorates, and the threshold voltage Vth change under NBTIS conditions may increase. Therefore, it is necessary to prevent damage to the active layer 130 and the channel part 130n without reducing the oxygen concentration of the gate insulating layer 140.

According to one embodiment of the present disclosure, a first protection layer 171 is disposed on a portion of the channel part 130n and the drain connection part 130b. As a result, damage to the active layer 130 and the channel part 130n may be prevented without increasing the length of the channel part 130n and without reducing the oxygen concentration of the gate insulating layer 140.

In this way, according to one embodiment of the present disclosure, by disposing the first protection layer 171 on a part of the channel part 130n and on the drain connection part 130b, damage to the active layer 130 and the channel part 130n may be prevented. As a result, the thin film transistor 100, 200, 300, 400, 500, 600, 700 according to one embodiment of the present disclosure may have excellent driving stability.

Another embodiment of the present disclosure provides a display apparatus including the thin film transistor 100, 200, 300, 400, 500, 600, 700 described above.

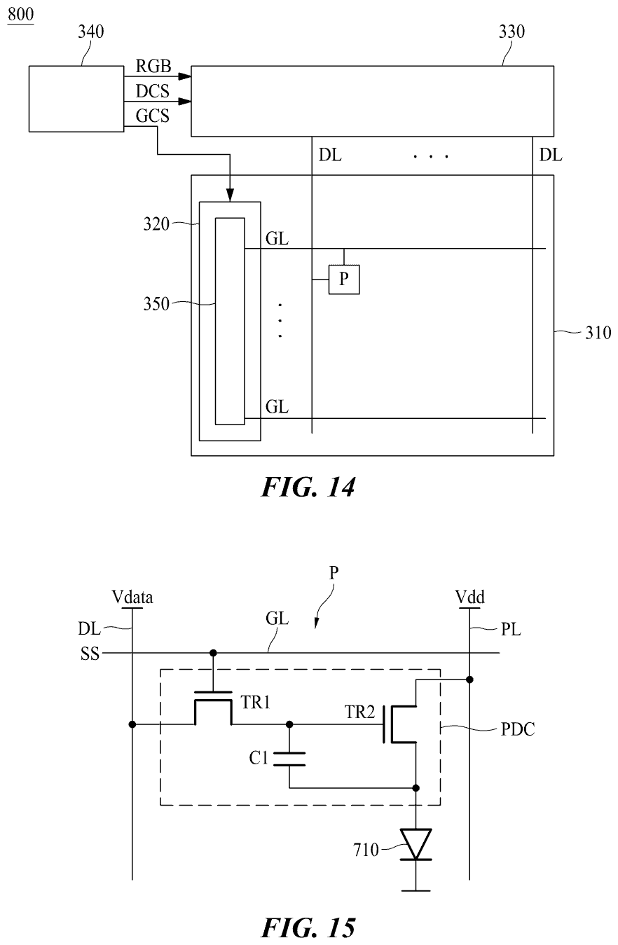

FIG. 14 is a schematic diagram of a display apparatus 800 according to another embodiment of the present disclosure.

A display apparatus 800 according to another embodiment of the present disclosure includes a display panel 310, a gate driver 320, a data driver 330, and a control unit 340, as illustrated in FIG. 14.

Gate lines GL and data lines DL are disposed on the display panel 310, and pixels P are arranged in the intersection area of the gate lines GL and data lines DL. An image is displayed by driving the pixels P.

The control unit 340 controls the gate driver 320 and the data driver 330.

The control unit 340 outputs a gate control signal GCS for controlling the gate driver 320 and a data control signal DCS for controlling the data driver 330 using a signal supplied from an external system. In addition, the control unit 340 samples input image data input from an external system, rearranges it, and supplies rearranged digital image data (RGB) to the data driver 330.

The gate control signal GCS includes a gate start pulse GSP, a gate shift clock GSC, a gate output enable signal GOE, a start signal Vst, and a gate clock GCLK. In addition, the gate control signal GCS may include control signals for controlling the shift register 350.

Data control signals DCS include source start pulse SSP, source shift clock signal SSC, source output enable signal SOE, and polarity control signal POL.

The data driver 330 supplies data voltage to the data lines DL of the display panel 310. In detail, the data driver 330 converts image data (RGB) input from the control unit 340 into analog data voltage and supplies the data voltage to the data lines DL.

The gate driver 320 may include a shift register 350.

The shift register 350 sequentially supplies gate pulses to the gate lines GL for one frame using a start signal and a gate clock transmitted from the control unit 340. Here, one frame refers to a period during which one image is output through the display panel 310. The gate pulse has a turn-on voltage capable of turning on a switching element thin film transistor arranged in a pixel P.

In addition, the shift register 350 supplies a gate off signal capable of turning off the switching element to the gate line GL during the remaining period during which the gate pulse is not supplied during one frame. Hereinafter, the gate pulse and the gate off signal are collectively referred to as a scan signal SS or Scan.

According to one embodiment of the present disclosure, the gate driver 320 may be mounted on the substrate 110. In this way, a structure in which the gate driver 320 is directly mounted on the substrate 110 is called a GIP (Gate In Panel) structure. The gate driver 320 may include at least one of the thin film transistors 100, 200, 300, 400, 500, 600, 700 described above.

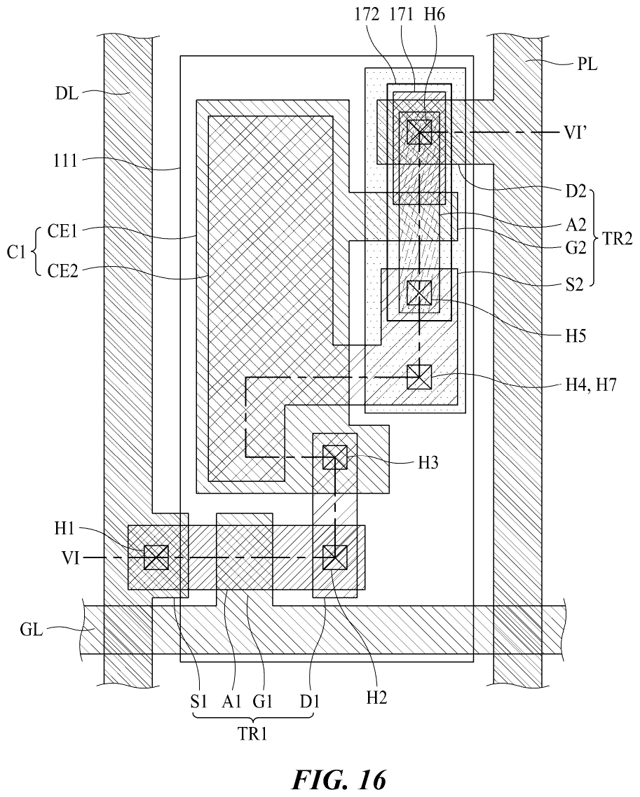

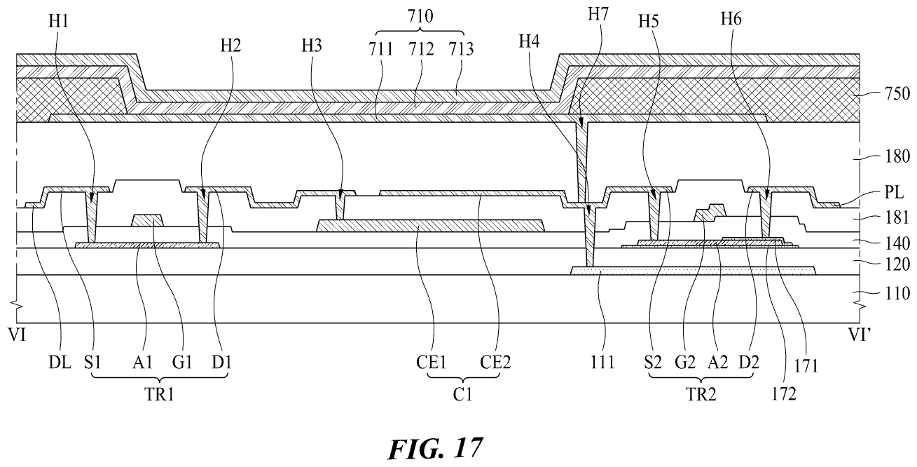

FIG. 15 is a circuit diagram for one pixel P of FIG. 14, FIG. 16 is a plan view for the pixel P of FIG. 15, and FIG. 17 is a cross-sectional view taken along line VI-VI′ of FIG. 16.

The circuit diagram of FIG. 15 is an equivalent circuit diagram for a pixel P of a display apparatus 800 including an organic light emitting diode (OLED) as a display element 710.

The pixel P includes a display element 710 and a pixel driver PDC that drives the display element 710.

The pixel driver PDC of FIG. 15 includes a first thin film transistor TR1 which is a switching transistor and a second thin film transistor TR2 which is a driving transistor.

A display apparatus 800 according to another embodiment of the present disclosure may include at least one of the thin film transistors 100, 200, 300, 400, 500, 600, 700 described above. As the first thin film transistor TR1 or the second thin film transistor TR2 of FIG. 15, any one of the thin film transistors 100, 200, 300, 400, 500, 600, 700 described above may be used.

The first thin film transistor TR1 is connected to the gate line GL and the data line DL, and is turned on or off by the scan signal SS supplied through the gate line GL.

The data line DL provides a data voltage Vdata to the pixel driver PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode (OLED), which is the display element 710.

When the first thin film transistor TR1 is turned on by a scan signal SS applied through the gate line GL from the gate driver 320, the data voltage Vdata supplied through the data line DL is supplied to the gate electrode G2 of the second thin film transistor TR2 connected to the display element 710 (see for example FIG. 16 and FIG. 17). The data voltage Vdata is charged in the first capacitor C1 formed between the gate electrode G2 and the source electrode S2 of the second thin film transistor TR2. The first capacitor C1 is a storage capacitor Cst.

The amount of current supplied to the organic light emitting diode (OLED), which is a display element 710, through the second thin film transistor TR2 is controlled according to the data voltage Vdata, and accordingly, the gradation of light output from the display element 710 may be controlled.

Referring to FIG. 16 and FIG. 17, a first thin film transistor TR1 and a second thin film transistor TR2 are disposed on a substrate 110.

The substrate 110 may be made of glass or plastic. As the substrate 110, a plastic having flexible properties, for example, polyimide (PI), may be used.

A light blocking layer 111 is disposed on the substrate 110. The light blocking layer 111 may protect the active layer A2 by blocking light incident from the outside.

Although a configuration in which a light blocking layer 111 is arranged under the active layer A2 of the second thin film transistor TR2 is illustrated in FIGS. 16 and 17, another embodiment of the present disclosure is not limited thereto. A light blocking layer 111 may also be disposed under the active layer A1 of the first thin film transistor TR1.

The buffer layer 120 is disposed on the light blocking layer 111. The buffer layer 120 is made of an insulating material and protects the active layers A1, A2 from moisture or oxygen flowing in from the outside.

An active layer A1 of a first thin film transistor TR1 and an active layer A2 of a second thin film transistor TR2 are disposed on a buffer layer 120.

The active layers A1, A2 include an oxide semiconductor material. According to another embodiment of the present disclosure, the active layers A1, A2 are oxide semiconductor layers made of an oxide semiconductor material.

A second protection layer 172 is disposed on the lower surface of the active layer A1, A2, and a first protection layer 171 is disposed on the upper surface and side surface of the active layer A1, A2. The first protection layer 171 may cover only a part of the active layer A1, A2. The first protection layer 171 covers a part of the channel part of the active layer A1, A2.

In FIG. 16 and FIG. 17, a first protection layer 171 is disposed on an active layer A2 of a second thin film transistor TR2, and a second protection layer 172 is disposed on a lower surface of the active layer A2 of the second thin film transistor TR2. On the other hand, referring to FIG. 16 and FIG. 17, the first protection layer 171 and the second protection layer 172 are not disposed on the first thin film transistor TR1. However, another embodiment of the present disclosure is not limited thereto, and the first protection layer 171 and the second protection layer 172 may also be disposed on the first thin film transistor TR1.

The first protection layer 171 contains the same metal as the oxide semiconductor material and may have a resistivity greater than that of the active layers A1, A2.

The gate insulating layer 140 is disposed on the first protection layer 171. The gate insulating layer 140 has insulating property and separates the active layers A1, A2 from the gate electrodes G1, G2, respectively. As illustrated in FIG. 17, the gate insulating layer 140 may not be patterned. However, another embodiment of the present disclosure is not limited thereto, and the gate insulating layer 140 may be patterned.

A gate electrode G1 of a first thin film transistor TR1 and a gate electrode G2 of a second thin film transistor TR2 are disposed on a gate insulating layer 140.

The gate electrode G1 of the first thin film transistor TR1 overlaps with the active layer A1 of the first thin film transistor TR1. The gate electrode G2 of the second thin film transistor TR2 overlaps with the active layer A2 of the second thin film transistor TR2.

Referring to FIGS. 16 and 17, the first capacitor electrode CE1 of the first capacitor C1 is disposed on the same layer as the gate electrodes G1, G2. The gate electrodes G1, G2 and the first capacitor electrode CE1 may be manufactured together by the same process using the same material.

An interlayer insulating layer 181 is disposed on the gate electrodes G1, G2 and the first capacitor electrode CE1.

A source electrode S1, S2 and a drain electrode D1, D2 are disposed on an interlayer insulating layer 181. According to one embodiment of the present disclosure, the source electrodes S1, S2 and the drain electrodes D1, D2 are distinguished only for convenience of explanation, and the source electrodes S1, S2 and the drain electrodes D1, D2 may be interchanged with each other. Accordingly, the source electrodes S1, S2 may become the drain electrodes D1, D2, and the drain electrodes D1, D2 may become the source electrodes S1, S2.

In addition, a data line DL and a driving power line PL are disposed on the interlayer insulating layer 181. The source electrode S1 of the first thin film transistor TR1 may be formed integrally with the data line DL. The drain electrode D2 of the second thin film transistor TR2 may be formed integrally with the driving power line PL.

According to one embodiment of the present disclosure, the source electrode S1 and the drain electrode D1 of the first thin film transistor TR1 are spaced apart from each other and are respectively connected to the active layer A1 of the first thin film transistor TR1. The source electrode S2 and the drain electrode D2 of the second thin film transistor TR2 are spaced apart from each other and are respectively connected to the active layer A2 of the second thin film transistor TR2.

In detail, the source electrode S1 of the first thin film transistor TR1 contacts the source connection part of the active layer A1 through the first contact hole H1.

The drain electrode D1 of the first thin film transistor TR1 contacts the drain connection part of the active layer A1 through the second contact hole H2 and is connected to the first capacitor electrode CE1 through the third contact hole H3.

The source electrode S2 of the second thin film transistor TR2 extends over the interlayer insulating layer 181, and a portion of it functions as a second capacitor electrode CE2. The first capacitor electrode CE1 and the second capacitor electrode CE2 overlap to form a first capacitor C1.

The source electrode S2 of the second thin film transistor TR2 contacts the light blocking layer 111 (which also may be called light shielding layer) through the fourth contact hole H4 and contacts the source connection part of the active layer A2 through the fifth contact hole H5.

The drain electrode D2 of the second thin film transistor TR2 contacts the drain connection part of the active layer A2 through the sixth contact hole H6.

The first thin film transistor TR1 includes an active layer A1, a gate electrode G1, a source electrode S1, and a drain electrode D1, and acts as a switching transistor that controls the data voltage Vdata applied to the pixel driver PDC.

The second thin film transistor TR2 includes an active layer A2, a first protection layer 171, a second protection layer 172, a gate electrode G2, a source electrode S2, and a drain electrode D2, and serves as a driving transistor that controls the driving voltage Vdd applied to the display element 710.

A planarization layer 180 is disposed on the source electrodes S1, S2, the drain electrodes D1, D2, the data line DL, and the driving power line PL. The planarization layer 180 planarizes the upper surfaces of the first thin film transistor TR1 and the second thin film transistor TR2, and protects the first thin film transistor TR1 and the second thin film transistor TR2.

The first electrode 711 of a display element 710 is disposed on a planarization layer 180. The first electrode 711 of the display element 710 is connected to a source electrode S2 of a second thin film transistor TR2 through a seventh contact hole H7 formed in the planarization layer 180.

A bank layer 750 is arranged at the edge of the first electrode 711. The bank layer 750 defines a light emitting area of the display element 710.

An organic light emitting layer 712 is disposed on a first electrode 711, and a second electrode 713 is disposed on the organic light emitting layer 712. Accordingly, a display element 710 is completed. The display element 710 illustrated in FIG. 17 is an organic light emitting diode (OLED). Therefore, a display apparatus 100 according to an embodiment of the present disclosure is an organic light emitting display apparatus.

A pixel driver PDC according to another embodiment of the present disclosure may be formed in various structures other than the structures described above. The pixel driver PDC may include, for example, three or more thin film transistors and two or more capacitors.

The present disclosure described above is not limited to the above described embodiments and the attached drawings, and it will be apparent to a person skilled in the art to which the present disclosure pertains that various substitutions, modifications, and changes are possible within a scope that does not depart from the technical details of the present disclosure.

According to one embodiment of the present disclosure, by disposing a first protection layer on an active layer, the stability of the active layer and the operating stability of the thin film transistor may be improved. According to one embodiment of the present disclosure, the first protection layer may include the same metal as the oxide semiconductor material.

According to another embodiment of the present disclosure, the first protection layer made of an oxide semiconductor material but having a high oxygen concentration is disposed on the active layer, whereby the stability of the active layer is improved, and as a result, the stability of the thin film transistor may be improved.

According to one embodiment of the present disclosure, the first protection layer and the second protection layer including the same metal as the oxide semiconductor material are respectively disposed on the upper and lower surfaces of the active layer, thereby protecting the active layer. As a result, damage to the active layer may be prevented.

The display apparatus according to one embodiment of the present disclosure includes a thin film transistor having excellent stability as described above. As a result, the display apparatus according to one embodiment of the present disclosure may exhibit stable display performance.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer;
a first protection layer on the active layer; and
a gate electrode spaced apart from the active layer and the first protection layer,
wherein the active layer comprises:
a channel part overlapping the gate electrode;
a source connection part connected to one side of the channel part; and
a drain connection part connected to the other side of the channel part,
wherein the first protection layer contacts a portion of the channel part and the drain connection part, and
wherein a portion of the first protection layer overlaps the gate electrode.

2. The thin film transistor of claim 1,
wherein the first protection layer is integrally formed on an upper surface of a portion of the channel part and on upper surface of the drain connection part.

3. The thin film transistor of claim 1,
wherein the first protection layer contacts a side surface of a portion of the channel part and a side surface of the drain connection part.

4. The thin film transistor of claim 1,
wherein the first protection layer includes at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, a GO (GaO) based oxide semiconductor material, a TO (SnO) based oxide semiconductor material, an ITO (InSnO) based oxide semiconductor material, and an ITZO (InSnZnO) based oxide semiconductor material.

5. The thin film transistor of claim 1,
wherein the active layer and the first protection layer include a same metal.

6. The thin film transistor of claim 5,
wherein the active layer and the first protection layer each include gallium (Ga), and a gallium concentration of the first protection layer is higher than a gallium concentration of the active layer,
wherein the gallium concentration of the first protection layer is calculated as a ratio of the number of gallium (Ga) atoms to the total number of atoms in the first protection layer atomic %, at %, and
wherein the gallium concentration of the active layer is calculated as a ratio of the number of gallium (Ga) atoms to the total number of atoms in the active layer atomic %, at %.

7. The thin film transistor of claim 1,
wherein the first protection layer has a resistivity higher than a resistivity of the active layer.

8. The thin film transistor of claim 1,
wherein the first protection layer has a resistivity of 1.0×10⁶ Ω·cm or more.

9. The thin film transistor of claim 1,
wherein the first protection layer has a carrier concentration lower than a carrier concentration of the active layer.

10. The thin film transistor of claim 9,
wherein the first protection layer has a carrier concentration of 1.0×10¹⁶ ea/cm³ or less.

11. The thin film transistor of claim 1,
wherein the first protection layer has an oxygen concentration higher than an oxygen concentration of the active layer.

12. The thin film transistor of claim 1,
wherein the first protection layer has a thickness of 0.5 to 3 nm.

13. The thin film transistor of claim 1,
wherein an overlap length between the first protection layer and the channel part is less than or equal to half the length of the channel part, and
wherein the length of the channel part is a distance between the source connection part and drain connection part, and the overlap length is measured in a direction parallel to a line connecting the source connection part and drain connection part.

14. The thin film transistor of claim 1 further comprising:
a second protection layer contacting the active layer,
wherein the active layer is on the second protection layer.

15. The thin film transistor of claim 14,
wherein the first protection layer extends to a side surface of the channel part and a side surface of the drain connection part and contacts the second protection layer.

16. The thin film transistor of claim 14,
wherein the second protection layer includes at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, a GO (GaO) based oxide semiconductor material, a TO (SnO) based oxide semiconductor material, an ITO (InSnO) based oxide semiconductor material, and an ITZO (InSnZnO) based oxide semiconductor material.

17. The thin film transistor of claim 16,
wherein the active layer and the second protection layer each include gallium (Ga), and a gallium (Ga) concentration of the second protection layer is higher than a gallium (Ga) concentration of the active layer.

18. The thin film transistor of claim 14,
wherein the second protection layer includes a first region overlapping the active layer and a second region not overlapping the active layer, wherein the first region has a thickness greater than a thickness of the second region.

19. The thin film transistor of claim 1,
wherein the active layer comprises:
a first oxide semiconductor layer; and
a second oxide semiconductor layer on the first oxide semiconductor layer,
wherein the first protection layer includes a same metal as the second oxide semiconductor layer.

20. The thin film transistor of claim 14,
wherein the active layer comprises:
a first oxide semiconductor layer; and
a second oxide semiconductor layer on the first oxide semiconductor layer,
wherein the second protection layer includes a same metal as the first oxide semiconductor layer.

21. A display apparatus comprising:
a display element;
a thin film transistor connected to the display element, the thin film transistor including:
an active layer;
a first protection layer on the active layer; and
a gate electrode spaced apart from the active layer and the first protection layer,
wherein the active layer comprises:
a channel part overlapping the gate electrode;
a source connection part connected to one side of the channel part; and
a drain connection part connected to the other side of the channel part,
wherein the first protection layer contacts a portion of the channel part and the drain connection part, and
wherein a portion of the first protection layer overlaps the gate electrode.
